(19) United States
(12) Patent Application Publication
(10) Pub. No.: US 2016/0218429 A1
(43) Pub. Date: Jul. 28, 2016

(54) PHASE CONTROL FOR ANTENNA ARRAY

(71) Applicant: HUAWEI TECHNOLOGIES CANADA CO., LTD., KANATA (CA)

(72) Inventor: MAREK KLEMES, KANATA (CA)

(21) Appl. No.: 14/603,908

(22) Filed: Jan. 23, 2015

(51) Int. Cl. H01Q 3/34; H03K 5/01

(52) U.S. Cl. CPC H01Q 3/34; H03K 5/01; H03K 2005/00286

(57) ABSTRACT

Phase control apparatus and methods for antenna arrays are disclosed. Phase shifts at respective antenna element subunits along a first axis of an antenna array are controlled by applying a variable control voltage across a voltage divider to divide the variable control voltage into multiple voltages that are used to generate phase shift control voltages for phase shift elements corresponding to the respective antenna element subunits. The antenna array may be steered along the first axis by controlling the variable control voltage applied across the voltage divider. A second voltage divider could be used to extend phase control and steering to two dimensions.

### FIELD OF THE APPLICATION

The application relates to wireless communication systems generally and more particularly to phase control in antenna array systems.

### BACKGROUND

Antenna arrays with multiple antenna elements are used in various types of communication equipment. By controlling the phase of signals that are fed to or received from elements of the antenna array, it is possible to steer the beams of the antenna array. This is referred to as beam steering. Phase control may be applied to signals for transmission from the antenna array and/or to signals that are received over the air by an antenna array.

### SUMMARY

An embodiment provides a phase control apparatus. The apparatus may include a first control voltage source for providing a first variable control voltage and a first voltage divider to divide the first variable control voltage into a first set of divided voltages. The apparatus may also include multiple phase shift elements, each coupled to the first voltage divider to receive a respective divided voltage of the first set of divided voltages.

In some embodiments, each phase shift element applies a respective phase shift to a signal received at an input of the phase shift element dependent on a magnitude of its respective divided voltage.

In some embodiments, each phase shift element is configured to apply its respective phase shift to a signal associated with a respective antenna element subunit in an antenna array.

The antenna element subunits in the antenna array may be distributed along a first axis in some embodiments.

In some embodiments, the respective divided voltage received by each phase shift element is proportional to a position, along the first axis, of the antenna element subunit associated with the phase shift element.

The antenna element subunits in the antenna array may also be distributed along a second axis in some embodiments.

An apparatus could also include a second control voltage source for providing a second variable control voltage and a second voltage divider to divide the second variable control voltage into a second set of divided voltages.

In some embodiments that include a second voltage divider, each phase shift element could also be coupled to the second voltage divider to receive a respective divided voltage of the second set of divided voltages, with each phase shift element applying its respective phase shift further dependent on a magnitude of its respective divided voltage of the second set of divided voltages.

In some embodiments, the respective divided voltage, of the second set of divided voltages, received by each phase shift element is proportional to a position, along the second axis, of the antenna element subunit associated with the phase shift element.

An apparatus could also include an antenna array with antenna element subunits distributed in a planar array in a plane defined by a first axis and a second axis.

In some embodiments, the antenna element subunits are arranged in the planar array in a grid pattern in columns along the first axis of the antenna array and in rows along the second axis of the antenna array.

The first voltage divider could include a first group of voltage dividers coupled together in parallel and distributed along the second axis of the antenna array in some embodiments. Similarly, the second voltage divider could include a second group of voltage dividers coupled together in parallel and distributed along the first axis of the antenna array. In some such embodiments, the phase shift elements may be coupled to the first voltage divider and the second voltage divider, with the phase shift element that is coupled to the antenna element subunit that is located at an m-th position of a planar array along the first axis and the n-th position of the planar array along the second axis being coupled to the m-th voltage divider of the second group of voltage dividers distributed along the first axis and the n-th voltage divider of the first group of voltage dividers distributed along the second axis.

In some embodiments, each phase shift element may include a phase shift driver that is configured to apply a calibration factor and/or an offset to the respective divided voltage to generate a calibrated divided voltage. In some such embodiments, each phase shift element may be configured to apply its respective phase shift dependent on a magnitude of the calibrated divided voltage generated by its phase shift driver.

The first variable control voltage may be provided by applying a positive voltage at a first end of the first voltage divider and a negative voltage at a second, opposite end of the first voltage divider.

In some embodiments, each phase shift element may include a phase shift driver configured to sum the respective divided voltage of the first set of divided voltages and the respective divided voltage of the second set of divided voltages. In some such embodiments, each phase shift element may be configured to apply its respective phase shift dependent on the resulting sum. The phase shift driver may also be configured to apply a calibration factor and/or an offset to the resulting sum to generate a calibrated phase shift control voltage. In some such embodiments, each phase shift element may be configured to apply its respective phase shift dependent on the calibrated phase shift control voltage generated by its phase shift driver.

In some embodiments, the respective divided voltage received by each phase shift element is proportional to a non-linear function of a position, along the first axis, of the antenna element subunit associated with the phase shift element.

Communication equipment that includes an antenna array with multiple antenna element subunits could also include a phase controller. The phase controller could include an apparatus as described above, coupled to the antenna element subunits of the antenna array, where each antenna element subunit includes at least one antenna element of the antenna array.

A phase control method is also disclosed, and could involve providing a first variable control voltage, dividing the first variable control voltage into a first set of divided voltages, and, at each of multiple phase shift elements, receiving a respective divided voltage of the first set of divided voltages and applying a respective phase shift to a signal dependent on a magnitude of the respective divided voltage of the first set of divided voltages.

In some embodiments, applying a respective phase shift includes applying a respective phase shift to a signal associated with a respective antenna element subunit in an antenna array.

The antenna element subunits in the antenna array may be distributed along a first axis in some embodiments. In some such embodiments, dividing the first variable control voltage includes dividing the first variable control voltage such that the respective divided voltage received by each phase shift element is proportional to a position, along the first axis, of the antenna element subunit associated with the phase shift element.

In some embodiments, the antenna element subunits in the antenna array may also be distributed along a second axis. In some such embodiments, a method may further include providing a second variable control voltage and dividing the second variable control voltage into a second set of divided voltages. Each phase shift element may receive a respective divided voltage of the second set of divided voltages, and apply the respective phase shift further dependent on a magnitude of the respective divided voltage of the second set of divided voltages.

In some embodiments, the second variable control voltage is divided such that the respective divided voltage, of the second set of divided voltages, received by each phase shift element is proportional to a position, along the second axis, of the antenna element subunit associated with the phase shift element.

In some embodiments, the respective divided voltage of the first set of divided voltages and the respective divided voltage of the second set of divided voltages may be summed, and the phase shift element may apply its respective phase shift to the signal dependent on the resulting sum.

In some embodiments, a calibration factor and/or an offset may be applied to the resulting sum to generate a calibrated phase shift control voltage and the phase shift element may apply its respective phase shift to the signal e dependent on the calibrated phase shift control voltage.

### BRIEF DESCRIPTION OF THE DRAWINGS

Embodiments will now be described with reference to the attached drawings in which:

FIG. 1 is a block diagram of an example communication system;

FIG. 2 is a block diagram of example communication equipment;

FIG. 3 is a diagram of an example uniform linear antenna array showing phases of a plane wave at elements of the uniform linear array;

FIG. 4 is a diagram of an example voltage divider;

FIG. 5 is a diagram of an example two-dimensional (2D) planar antenna array;

FIG. 6 is a diagram of an example phase controller for controlling phase in a 2D planar antenna array;

FIG. 7 is a diagram of an example voltage summing circuit that may be used in a phase shift element in a phase controller;

FIG. 8 is a block diagram of an example phase shift element that may be used in a phase controller;

FIG. 9 is a block diagram of an example calibrator circuit that may be used in a phase shift driver as part of a phase shift element in a phase controller;

FIG. 10 is a block diagram of an example phase shift element implemented in a phase locked loop;

FIG. 11 is a diagram of another example phase controller for controlling phase in a 2D planar antenna array;

FIG. 12 is a diagram of a section of an example continuous resistance;

FIG. 13 is a diagram of another example phase controller for controlling phase for a 2D planar antenna array;

FIG. 14 is a diagram of an example active radio frequency (RF) lens function overlaid on a 2D planar antenna array;

FIG. 15 is a flow diagram of an example method; and

FIG. 16 is a flow diagram of another example method.

### DETAILED DESCRIPTION OF EMBODIMENTS

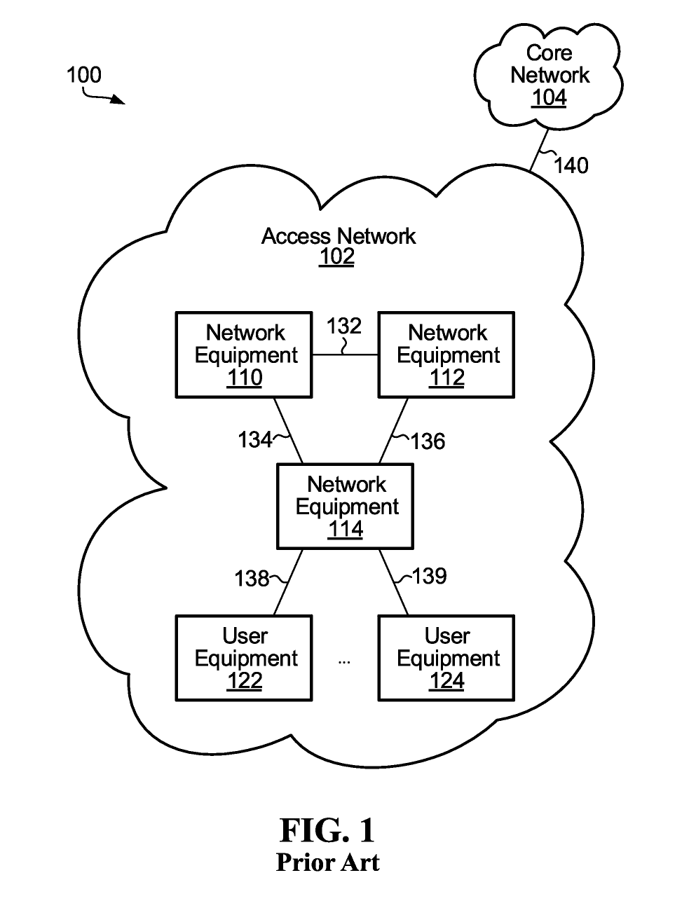

FIG. 1 is a block diagram of an example communication system in which embodiments of the present disclosure could be implemented. The example communication system 100 in FIG. 1 includes an access network 102 and a core network 104. The access network 102 includes network equipment 110, 112, 114 which communicates over network communication links 132, 134, 136, and user equipment 122, 124 which communicates with network equipment 114 in the example shown, over access communication links 138, 139. The access network 102 communicates with the core network 104 over another network communication link 140. The core network 104, like the access network 102, may include network equipment that communicates with one or more installations of the network equipment 110, 112 114 in the access network 102. However, in a communication system with an access network 102 and a core network 104, the core network might not itself directly provide communication service to user equipment.

The communication system 100 is intended solely as an illustrative example. An access network 102 could include more or fewer than three installations of network equipment, for example, which might or might not all directly communicate with each other as shown. Also, more than one installation of network equipment in the access network 102 could provide communication service to user equipment. There could be more than one access network 102 coupled to a core network 104. It should also be appreciated that the present disclosure is not in any way limited to communication systems having an access network/core network structure.

More generally, FIG. 1, as well as the other drawings, are intended solely for illustrative purposes. The present disclosure is not limited to the particular example embodiments explicitly shown in the drawings.

Considering first the access network 102, any of various implementations are possible. The exact structure of network equipment 110, 112, 114, and user equipment 122, 124 for which such network equipment provides communication service, is implementation-dependent.

At least the network equipment 114 that provides communication service to the user equipment 122, 124 includes a physical interface and communications circuitry to support access-side communications with the user equipment over the access links 138, 139. The access-side physical interface could be in the form of an antenna or an antenna array, for example, where the access communication links 138, 139 are wireless links. In the case of wired access communication links 138, 139, an access-side physical interface could be a port or a connector to a wired communication medium. Multiple access-side interfaces could be provided at the network equipment 114 to support multiple access communication links 138, 139 of the same type or different types, for instance. The type of communications circuitry coupled to the access-side physical interface(s) at the access network equipment 114 is dependent upon the type(s) of access communication links 138, 139 and the communication protocol(s) used to communicate with the user equipment 122, 124.

The network equipment 110, 112, 114 also includes a network-side physical interface, or possibly multiple network-side physical interfaces, and communications circuitry to enable communications with other network equipment in the access network 102. At least some installations of network equipment 110, 112, 114 also include one or more network-side physical interfaces and communications circuitry to enable communications with core network equipment over the communication link 140. There could be multiple communication links between network equipment 110, 112, 114 and the core network 104. Network-side communication links 132, 134, 136 that are in the access network 102, and the communication link 140 to the core network 104, could be the same type of communication link. In this case, the same type of physical interface and the same communications circuitry at the network equipment 110, 112, 114 could support communications between access network equipment within the access network 102 and between the access network 102 and the core network 104. Different physical interfaces and communications circuitry could instead be provided at the network equipment 110, 112, 114 for communications within the access network 102 and between the access network 102 and the core network 104.

Network equipment in the core network 104 could be similar in structure to the network equipment 110, 112, 114. However, as noted above, network equipment in the core network 104 might not directly provide communication service to user equipment and therefore might not include access-side physical interfaces for access communication links or associated access-side communications circuitry. Physical interfaces and communications circuitry at network equipment in the core network 104 could support the same type(s) of network communication link(s) as in the access network 102, different type(s) of network communication link(s), or both.

Just as the exact structure of physical interfaces at network equipment 110, 112, 114 and network equipment in the core network 104 is implementation-dependent, the associated communications circuitry is implementation-dependent as well. In general, hardware, firmware, components which execute software, or some combination thereof, might be used in implementing such communications circuitry. Electronic devices that might be suitable for implementing communications circuitry include, among others, microprocessors, microcontrollers, Programmable Logic Devices (PLDs), Field Programmable Gate Arrays (FPGAs), Application Specific Integrated Circuits (ASICs), and other types of “intelligent” integrated circuits. Software could be stored in memory for execution. The memory could include one or more physical memory devices, including any of various types of solid-state memory devices and/or memory devices with movable or even removable storage media.

Each installation of user equipment 122, 124 includes a physical interface and communications circuitry compatible with an access-side physical interface and communications circuitry at the network equipment 114, to enable the user equipment to communicate with the network equipment. Multiple physical interfaces of the same or different types could be provided at the user equipment 122, 124. The user equipment 122, 124 could also include such components as input/output devices through which functions of the user equipment are made available to a user. In the case of a wireless communication device such as a smartphone, for example, these functions could include not only communication functions, but other local functions which need not involve communications. Different types of user equipment 122, 124, such as different smartphones for instance, could be serviced by the same network equipment 114.

Any of the communication links 132, 134, 136, 138, 139, 140, and communication links in the core network 104 could potentially be or include wireless communication links. Such communication links tend to be used more often within an access network 102 than in a core network 104, although wireless communication links at the core network level are possible. An antenna array including multiple antenna elements could be used at each end of a wireless communication link to enable communications over the air.

Beam steering, also often included in the capability of beamforming, exploits the effects of signal phase changes on antenna beam characteristics in a multiple-element antenna array. In a transmit direction, different phase shifts are applied to the same antenna feed signal, which is to be transmitted via the antenna array. The phase shifted versions of the signal, to which the different phase shifts have been applied, are supplied to respective antenna element subunits. Each antenna element subunit may include a single antenna element or multiple antenna elements, possibly arranged in a 1D or 2D sub-array. In a receive direction, inverse phase shifts are applied to signals received at corresponding antenna element subunits to generate a received signal for further processing. In some cases, amplitude shifts may also be applied, e.g. as part of a calibration function if phase shifter settings happen to affect the amplitude transfer of the phase shifter. However, for clarity, only phase control will be discussed in the subsequent description.

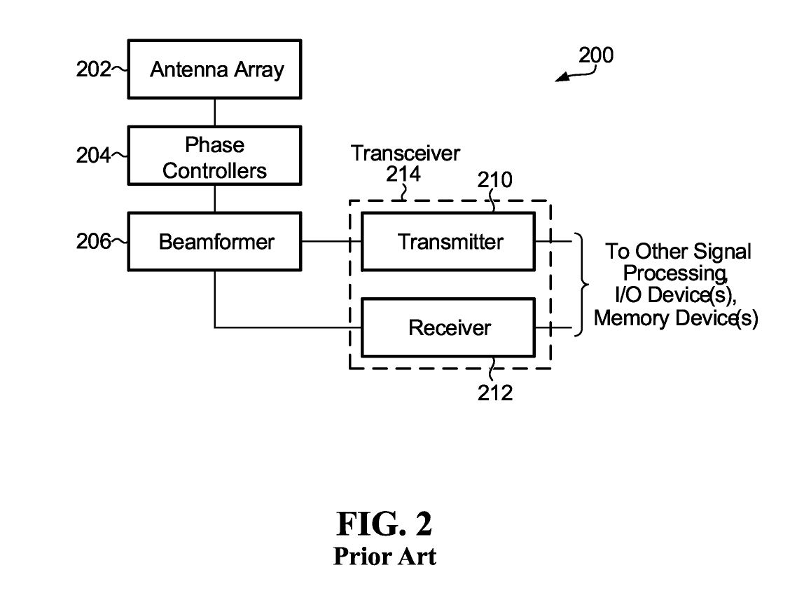

FIG. 2 is a block diagram of example communication equipment 200, which includes an antenna array 202. Phase controllers 204 are coupled to the antenna array 202 in the example shown, and a beamformer or feed network 206 is coupled to the phase controllers. A transmitter 210 and a receiver 212, which could be part of a transceiver 214, are coupled to the beamformer 206. The transmitter 210 and the receiver 212 could also be coupled to other components, such as other signal processing components which further process received signals or perform processing to generate signals for transmission on a wireless communication link through the antenna array 202, one or more input/output devices, and/or one or more memory devices.

The antenna array 202 includes multiple antenna elements, and is an example of a physical interface to a communication medium. The antenna elements could take any of various forms, depending on the type of radio equipment in which the components shown in FIG. 2 are implemented. In general, the size of an antenna element is dictated by the wavelength(s) of signals to be received and/or transmitted at the medium (air) interface.

The example communication equipment 200 could be communication network equipment or user equipment. In an embodiment, the components shown in FIG. 2 are implemented at both communication network equipment and user equipment, to enable communications between the network equipment 114 and the user equipment 122, 124 in FIG. 1, for example.

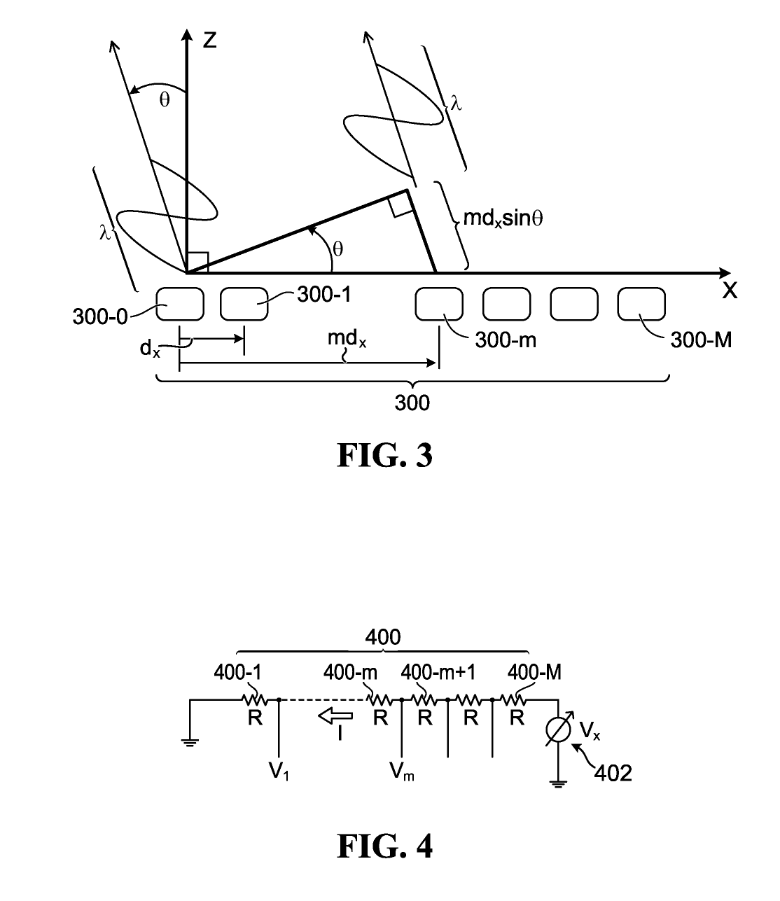

Examples of phase controllers 204 are discussed in further detail below with reference to FIGS. 3 to 14. Each of the phase controllers 204 is coupled to a respective antenna element subunit, each of which may include one or more antenna elements of the antenna array 202. In one embodiment, each of the phase controllers 204 is coupled to a respective single antenna element, although in other embodiments each phase controller is coupled to multiple antenna elements. A phase controller 204 could be coupled to multiple antenna elements, but each antenna element would usually be coupled to only one phase controller.

The beamformer 206 could be implemented in hardware, firmware, one or more components that execute software, or some combination thereof. The transmitter 210 and the receiver 212 could be implemented in hardware, firmware, one or more components that execute software, or some combination thereof. Communication equipment need not necessarily support both transmit and receive functions, and therefore in some embodiments only a transmitter 210 or only a receiver 212 might be provided.

Implementations of the various components of the example communication equipment 200 could be different for different types of communication equipment. As noted above, different types of antenna elements could be implemented in the antenna array 202 depending upon whether the example communication equipment 200 is user equipment or network equipment. Antenna element numbers and designs could depend not only on the physical space available for the antenna array 202, but also or instead on the frequency at which the antenna elements are to be operated and other characteristics of the wireless communication link(s) that are to be provided. It is also possible that communication equipment could include multiple antenna arrays, for different receive and transmit frequencies or different communication links for instance. Network equipment in an access network, for example, could include different antenna arrays for network-side communication links and access-side communication links. Designs of any of the beamformer 206, the transmitter 210, and the receiver 212 could also be different in different types of communication equipment.

In operation, the transmitter 210 could perform such operations as frequency up-conversion, encoding, and modulation, and the receiver 212 could perform inverse operations, including frequency down-conversion, decoding, and demodulation in this example. Transmitters and receivers could perform other operations instead of or in addition to these example operations, depending on the specific implementation and the type(s) of communication functions and protocol(s) to be supported.

Outgoing signals to be transmitted through the antenna array 202 are generated by the transmitter 210 and provided to the beamformer 206, which controls the phase shifts that are applied by the phase controllers 204. The beamformer 206 could also handle distribution of outgoing signals to the phase controllers 204, although this could instead be handled separately in other embodiments. The phase controllers 204 feed phase shifted transmit signals to the antenna element(s) in the antenna array 202 to which they are coupled.

In the receive direction, signals received at antenna elements of the antenna array 202 are provided to the phase controllers 204, which apply phase shifting to the received signals. The resultant shifted received signals are combined by the beamformer 206 to generate an incoming signal for processing by the receiver 212.

While the general concept of beam steering has been discussed above with reference to FIGS. 1 and 2 in the context of communication equipment, such as user equipment or network communication equipment, in the context of a communications system, more generally beam steering or beamforming may be implemented in any kind of radio transmitting and/or receiving equipment, for various purposes, such as to align a beam between communicating nodes, to scan an illuminating and sensing beam in radar, and to focus a beam in medical RF, for instance.

There are many techniques for determining phase shifts that are to be applied to antenna feed signals. Antenna feed signals could be signals for transmission by the antenna array 202 or signals received by the antenna array. The present disclosure relates to generating the control signals to control the phase shift elements that apply phase shifts to such antenna feed signals as part of, for example, a phase controller, such as phase controller 204 of FIG. 2.

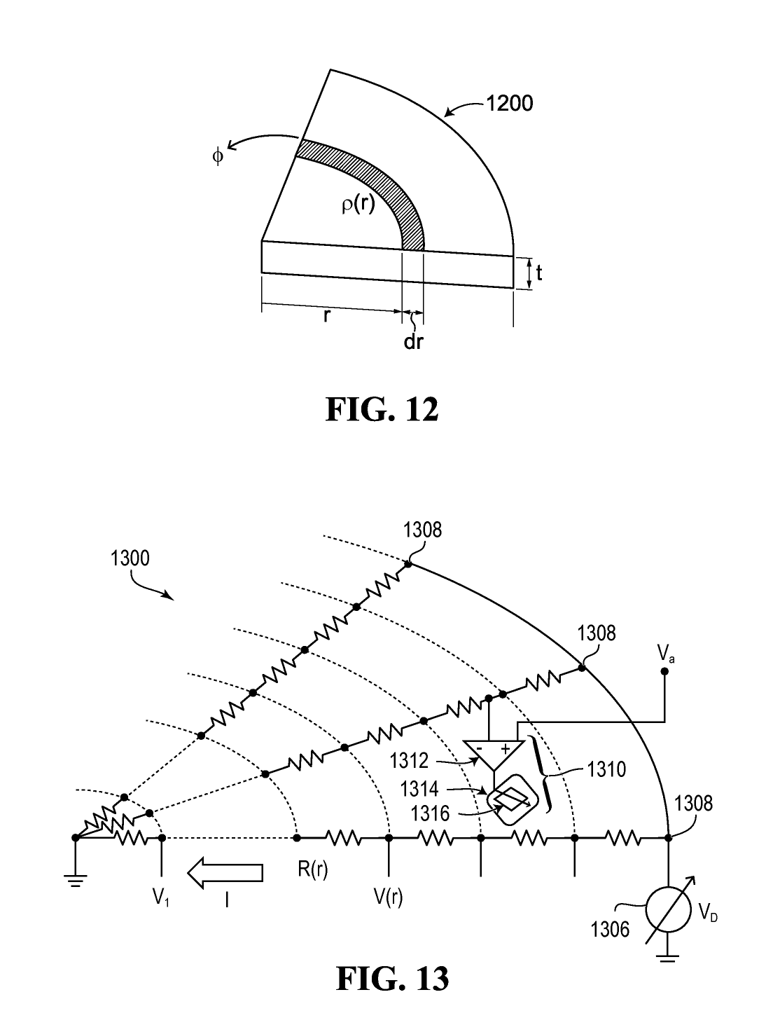

Beam steering is not the only functionality of an antenna array for which the control of signal phase may be utilized. For example, active RF lens functionality can be realized by adjusting the relative phase for the antenna elements of an antenna array according to a non-linear “lens” function, thereby adjusting the focal properties of the antenna array, rather than steering the antenna array. Active RF lens functionality is discussed in further detail below with reference to FIGS. 12 to 14.

Controlling the phase shifts applied by a plurality of phase shift elements, such as digital phase shifters, in order to control signal phase for an antenna array with many antenna elements, typically involves running several digital bit-control lines to each phase shifter and setting all the bits individually to steer the beam of the antenna array. Such implementations can be potentially be cumbersome and/or slow to respond, due to the fact that the desired phase is set independently and separately at each phase shifter. In addition, the space needed to route several digital bit-control lines to each phase shifter can become problematic, particularly in higher frequency applications, such as millimeter wave applications, where the size of the antenna array can be scaled with the wavelength, but the digital control circuitry for the phase shifters does not scale with wavelength. Because these control lines do not scale with wavelength, the space they consume becomes an even larger portion of the phased-array real-estate as radio frequency (RF) operating frequency increases and antenna arrays become smaller.

Other phase control schemes utilizing coupled local oscillators at each antenna element have been able to control signal phase and steering angle for an antenna array using only 1 or 2 control lines. However, such schemes involve tuning of the coupled oscillators in order to realize the desired phase shifts, which offsets the carrier frequency in proportion to the steering angle, thereby introducing a systematic frequency error.

Antenna arrays conforming to a regular rectangular grid geometry are conceptually simple to steer along 2 axes, but may be cumbersome to implement if, as noted above, each element is equipped with a digitally-controlled phase shifter requiring several bit-lines to select and set it.

However, it is not always necessary to have independent control of every phase shifter in a phased array. If the radio frequency (RF) phase shift is inherently proportional to a control voltage, such voltages can be generated by relatively simple analog means because they are simple (linear in case of steering) functions of the rectangular coordinates of the array geometry. It should be appreciated that references to voltages made herein are implicitly relative to a ground taken as 0 Volts, unless otherwise stated.

In many cases, relatively simple driving circuits can be used to effectively calibrate such control voltages to make the phase shifter control linear, by performing the associated scaling and offsetting locally as necessary, saving much real-estate otherwise consumed by the routing of many control-bit lines to each individual phase shifter.

Fortunately, there are simple relations that determine the phase setting of each antenna element subunit when it is required to steer a beam along the 2 axes of a rectangular planar antenna array, or to perform a focusing function perpendicular to its plane (as with an active RF lens). In some cases, these relationships can be naturally generated by relatively simple analog circuitry using only 2 independent control voltages (in case of 2-axes steering), regardless of the number of antenna element subunits.

An example of one dimensional steering along a linear antenna array will now be discussed with reference to FIG. 3.

FIG. 3 is a diagram of an example uniform linear antenna array that includes a plurality of antenna elements 300-0 300-1, . . . , 300-m, . . . , 300-M distributed at intervals of dₓ along a first direction (x-axis), receiving or transmitting a plane-wave signal with wavelength λ at angle θ with respect to the x-axis. The phase of the wave at the m-th antenna element 300-m relative to the phase of the wave at the element 300-0 at the origin is m times the phase at the first element 300-1 from the origin. This phase at the m-th antenna element 300-m is given by the ratio of the difference in distances travelled by the wave at the m-th antenna element 300-m and at the antenna element 300-0 to the wave's wavelength. The difference in propagation distances between any two adjacent elements separated by dₓ is dₓ sin θ. Therefore, the corresponding incremental phase shift between adjacent antenna elements is given by

$${ψ}_{x} = \frac{2 π}{λ} ( {d}_{x} sin θ ) \qquad ( 1 )$$

and at the m-th element the total effect of the m incremental phase shifts amounts to

$${ψ}_{m} = m {ψ}_{x} = \frac{2 π}{λ} ( {md}_{x} sin θ ) . \qquad ( 2 )$$

The phase shifts are negative when receiving (because the wavefronts are delayed relative to the origin), and positive when transmitting (because the wavefronts are advanced relative to the origin). That is, the corresponding time-domain factors that would multiply the received and transmitted signals are e^{-jψm} and e^{jψm}, respectively.

Strictly speaking, the above is true only for narrow-band signals, whose bandwidth is small (˜10% or less) relative to the reciprocal of the transit time of the wave across the span of the antenna array. True time-delays may be used in case of broad-band signals, so the time-delays would be proportional to the control voltages generated by the same voltage divider based arrangements described herein.

It is clear from FIG. 3 that the progression of the phase along the array is linear with the element displacement along the x-axis.

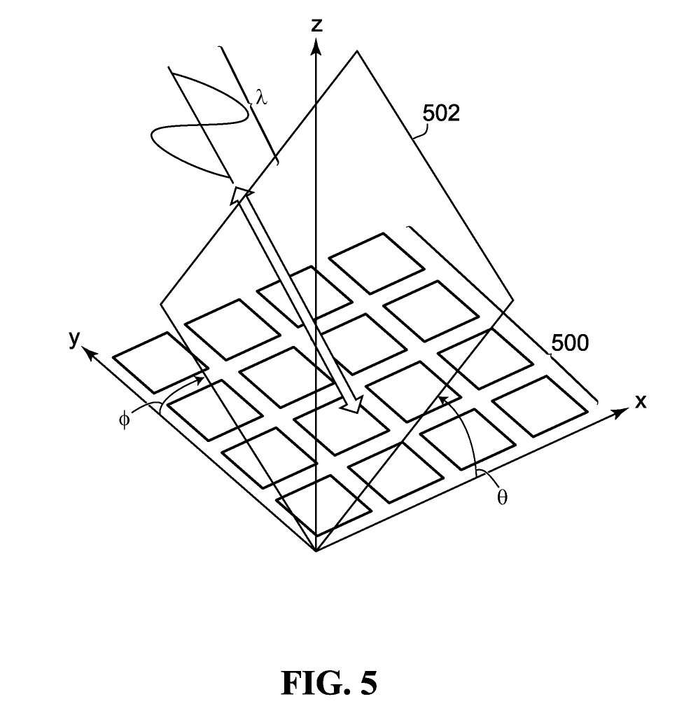

An analogous concept would be that of a voltage divider formed by a series of identical resistors coupled at one end to a variable voltage source and grounded at the other end, corresponding to 0 Volts at the reference, or origin point of the voltage divider. An example voltage divider 400 is shown in FIG. 4, coupled to a variable voltage source 402 that is configured to apply a variable voltage Vₓ across the voltage divider. Voltage divider 400 includes M serially coupled resistors 400-1 to 400-M of resistance R. The voltage Vₘ taken at the point between the m-th resistor 400-m and the (m+1)-th resistor 400-m+1, relative to the voltage at the origin, is a linear function of the m-th resistor's position in the voltage divider.

Conceptually, the variation of the variable voltage Vₓ applied across the voltage divider 400 by the variable voltage source 402 would correspond to the variation of the angle of propagation θ of the plane wave relative to the antenna array 300 (FIG. 3) and each resistor of resistance R would correspond to the uniform separation dₓ of adjacent elements 300-0, 300-1, 300-2, . . . , 300-m, . . . , 300-M in FIG. 3.

In the limit of a continuum, the phase at every position along the linear array aperture would correspond to an analogous voltage along a continuous linear resistance, so the elements and resistor taps would not have to be uniformly spaced, provided their positions along the axis maintained the same proportions as the positions of the elements.

The linear voltage relationship for the voltage divider 400 shown in FIG. 4 is easy to deduce using Ohm's law. First, for M resistors each having resistance R, one obtains the current I as

$$I = \frac{{V}_{x}}{MR} . \qquad ( 3 )$$

Assuming no current flows into any of the voltage tap points along the voltage divider, then at the first resistor 400-1 away from the grounded (0V reference) node the voltage V₁ is

$${V}_{1} = IR = \frac{{V}_{x}}{MR} R = \frac{{V}_{x}}{M} \qquad ( 4 )$$

so that at the m-th such resistor from the grounded node the voltage Vₘ is simply

$${V}_{m} = I ( mR ) = \frac{m {V}_{x}}{M} . \qquad ( 5 )$$

As such, if the variable control voltage Vₓ is made proportional to the sine of the steering angle θ as

$$\frac{{V}_{x}}{M} = C [ \frac{2 π {d}_{x}}{λ} ] sin θ \qquad ( 6 )$$

then the voltage Vₘ generated at the m-th resistor by the voltage divider will be proportional to the phase shift (effected electrical phase, φₘ), at the m-th antenna element corresponding to a plane wave propagating at angle θ to the x-axis as

$${V}_{m} = m \frac{{V}_{x}}{M} = mC [ \frac{( 2 π {d}_{x} )}{λ} ] sin θ = C {ψ}_{m} \qquad ( 7 )$$

where C is a calibration factor.

The above concept can be readily extended to steering a uniform rectangular planar antenna array along two axes. FIG. 5 is a diagram of an example two-dimensional (2D) planar antenna array 500. The example planar antenna array 500 shown in FIG. 5 includes 16 antenna elements arranged in a uniform grid pattern with four columns of antenna elements arranged along a first direction x of the antenna array and four rows of antenna elements arranged along the second direction y of the antenna array. The antenna elements are shown as blocks in FIG. 5. In the illustrated example, the planar antenna array 500 is steered for transmitting or receiving a plane-wave signal with wavelength λ at an angle θ relative to the first direction x of the antenna array and steered at an angle φ relative to the second direction y of the antenna array. Steering the planar antenna array 500 in this manner electronically tilts the plane 502 of the antenna array at an angle θ relative to the first direction x of the antenna array and at an angle φ relative to the second direction y of the antenna array, as shown in FIG. 5. Both angles are measured vertically from the plane of the array. More conventional steering angles, specifically azimuth (measured clockwise from the x- or y-axis in the plane of the array) and elevation (measured from the axis of the array perpendicular to it, toward the plane of the array) could also be used, with the net result that the control voltages applied to the voltage divider would become functions of both azimuth and elevation angles.

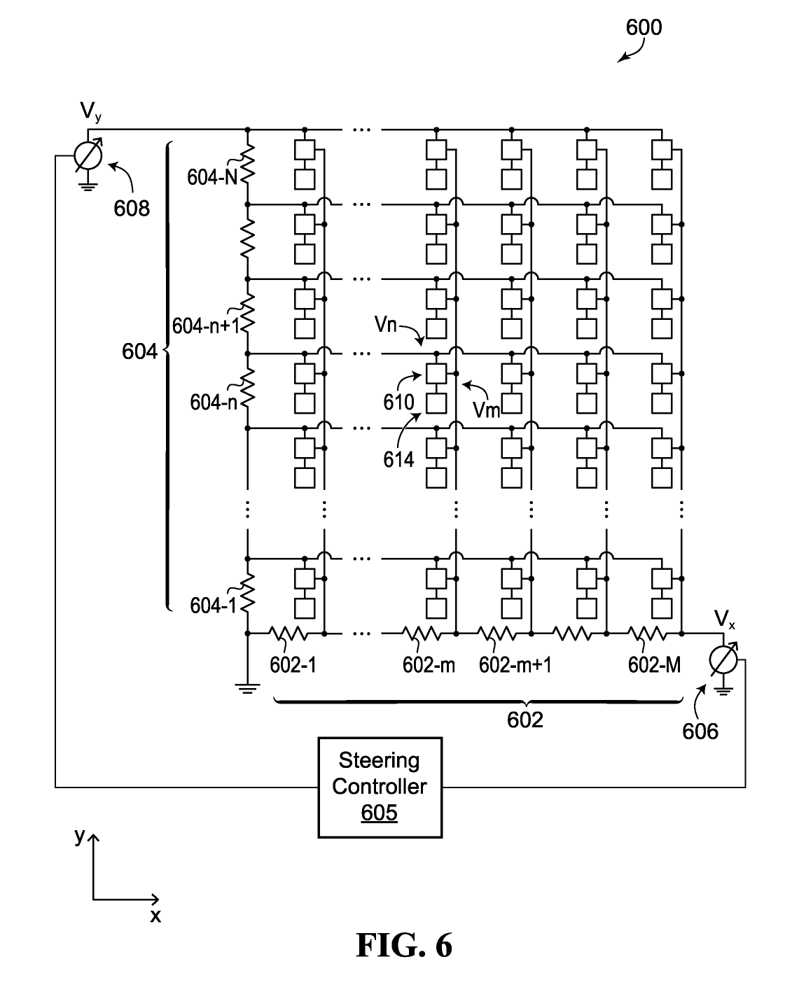

While the planar array 500 shown in FIG. 5 is a square 4×4 planar antenna array, embodiments are not limited to such antenna array arrangements. An apparatus for controlling signal phase for a rectangular M×N 2D planar antenna array will now be discussed with reference to FIG. 6.

FIG. 6 is a diagram of an example phase controller 600 for controlling phases for an M×N-subunit 2D planar antenna array.

The phase controller 600 includes a first voltage divider 602 coupled at one end to a voltage ground and coupled at its other end to a first variable voltage source 606, and a second voltage divider 604 coupled at one end to a voltage ground and coupled at its other end to a second variable voltage source 608.

The first voltage divider 602 includes a plurality of M resistors 602-1 to 602-M serially coupled together between the voltage ground and the first variable voltage source 606, while the second voltage divider 604 includes a plurality of N resistors 604-1 to 604-N serially coupled together between the voltage ground and the second variable voltage source 608.

The phase controller 600 also includes a plurality (M×N) of phase shift elements. Each phase shift element is coupled to the first voltage divider 602, the second voltage divider 604, and to a respective antenna element subunit of the plurality of M×N antenna element subunits of the planar antenna array. The phase shift element 610 that is coupled to an antenna element subunit 614 located at the m-th position in the first direction of the M×N planar antenna array and at the n-th position in the second direction of the M×N planar antenna array, is coupled to the first voltage divider 602 at a voltage tap between the m-th resistor 602-m and the (m+1)-th resistor 602-m+1 and is coupled to the second voltage divider 604 at a voltage tap between the n-th resistor 604-n and the (n+1)-th resistor 604-n+1.

All of the M×N phase shift elements may have the same structure in one embodiment. In other embodiments, the phase shift elements may not all have the same structure. Similarly, all of the antenna element subunits of the M×N planar antenna array may have the same structure in one embodiment. In other embodiments, the antenna element subunits may not all have the same structure.

Also shown in FIG. 6 is a steering controller 605, which is coupled to the first variable voltage source 606 and the second variable voltage source 608. The steering controller 605 could be implemented in hardware, firmware, or one or more components that execute software.

In operation, the first variable voltage source 606 applies a variable control voltage Vₓ across the first voltage divider 602 to generate M phase shift voltages at the M resistors 602-1 to 602-M of the first voltage divider and the second variable voltage source 608 applies a variable control voltage V_{y} across the second voltage divider 604 to generate N voltages at the N resistors 604-1 to 604-N of the second voltage divider.

Each of the phase shift elements applies a respective phase shift to a signal associated with its respective antenna element subunit. The respective phase shift is dependent on a respective m-th voltage of the M voltages generated by the first voltage divider 602 and on a respective n-th voltage of the N voltages generated by the second voltage divider 604.

The phase shift element 610 receives a voltage Vₘ from the voltage divider 602 and a voltage Vₙ from the voltage divider 604.

The phase shift element 610 sums the voltages Vₘ and Vₙ to generate a control voltage V_{m,n}, and applies a phase shift to a signal associated with the antenna element subunit 614 dependent on the control voltage V_{m,n}.

The steering controller 605 controls the phase progression along the x and y directions of the planar antenna array by controlling the variable control voltages Vₓ and V_{y}, thereby steering the planar antenna array in two dimensions.

If the antenna elements of a planar antenna array are arranged with a uniform spacing of dₓ between adjacent columns along the first direction x of the planar antenna array and a uniform spacing of d_{y} between adjacent rows along the second direction y of the planar antenna array, and if the M resistors 602-1 to 602-M of the first voltage divider 602 each have the same resistance Rₓ and the N resistors 604-1 to 604-N of the second voltage divider 604 each have the same resistance R_{y}, then it can be shown that, with reference to equations (5) to (7) above, at the m-th resistor 602-m along the first direction x the voltage Vₘ would be

$${V}_{m} = {I}_{x} ( {mR}_{x} ) = \frac{{mV}_{x}}{M} . \qquad ( 8 )$$

At the n-th resistor 604-n along the second direction y the voltage Vₙ would be

$${V}_{n} = {I}_{y} ( {nR}_{y} ) = \frac{{n V}_{y}}{N} . \qquad ( 9 )$$

The variable control voltage Vₓ applied across the first voltage divider 602 could be varied proportionally to the sine of a desired steering angle θ relative to the first direction x as

$$\frac{{V}_{x}}{M} = C [ \frac{2 π {d}_{x}}{λ} ] sin θ . \qquad ( 10 )$$

Similarly, the variable control voltage V_{y} applied across the second voltage divider 604 is made proportional to the sine of a steering angle φ relative to the second direction y as

$$\frac{{V}_{y}}{N} = C [ \frac{2 π {d}_{y}}{λ} ] sin φ . \qquad ( 11 )$$

As noted above, the phase shift element 610 sums the voltages Vₘ and Vₙ to generate a control voltage V_{m,n}.

If, as in some embodiments, each phase shift element also applies a calibration by applying at least one of a calibration factor and an offset to the sum of the respective voltages Vₘ and Vₙ, then with reference to equations (5) to (7), (10) and (11), the resulting calibrated control voltage V_{m,n} would be

$$\begin{matrix}{V}_{m , n} = {V}_{x} ( \frac{m}{M} ) + {V}_{y} ( \frac{n}{N} ) + {V}_{0} \\ = C \frac{2 π}{λ} ( {md}_{x} sin θ + {nd}_{y} sin φ + {d}_{0} ) \\ = C ( m {ψ}_{x} + n {ψ}_{y} + {ψ}_{0} ) \\ = C {ψ}_{m , n}\end{matrix} \qquad ( 12 )$$

where C is a calibration factor and V₀ is an offset or a bias voltage, as may be used depending on the type of phase shifter employed, and φ_{m,n} is the total phase shift (effected electrical phase) at the (m,n)-th antenna element

The phase shift elements could use different calibration and offset factors for each input voltage Vₘ and Vₙ. In some embodiments, the phase shift drivers may include an ADC (analog to digital converter), a latch, a DAC (digital to analog converter), a voltage-booster module, a temperature compensation module, a bias module, and/or any suitable combination thereof, which could be configured with calibration data.

From equation (12) above, it can be seen that a beam of the planar antenna array is steerable to a steering angle θ relative to the first direction x and a steering angle φ relative to the second direction y by controlling the variable control voltage Vₓ to be proportional to the sine of the steering angle θ and controlling the variable control voltage V_{y} to be proportional to the sine of the steering angle φ. The phase shift control voltage could be set for all M×N antenna element subunits by simply adjusting the 2 control voltages Vₓ and V_{y}.

It is noted that the two angular steering directions θ and φ do not correspond to the more conventional “azimuth” and “elevation” directions typically used to describe beam steering directions of phased arrays. However, it should be appreciated that the angular steering angles can be transformed into equivalent azimuth and elevation angles. Therefore, it should be appreciated that two angular steering angles θ and φ relative to the two antenna array directions x and y, respectively, can also be expressed in terms of azimuth and elevation angles. As such, rather than expressing the amplitude of the control voltage Vₓ as a function of the sine of the angular steering angle θ and the amplitude of the control voltage V_{y} as a function of the sine of the angular steering angle φ, the steering angles θ and φ could be transformed into equivalent azimuth and elevation angles. The amplitude of the control voltage Vₓ could similarly be expressed as a function of both the azimuth angle and the elevation angle and the amplitude of the control voltage V_{y} could be expressed as a function of both the azimuth angle and the elevation angle.

In some embodiments the control voltages Vₓ and V_{y} applied by the first variable voltage source 606 and the second variable voltage sources 608, respectively, are variable DC voltages. In other embodiments the variable voltage sources 606, 608 may generate non-DC control voltages, such as for example variable pulse-widths (as in Pulse-Width Modulation) or pulse repetition-rates (PRR). In such embodiments, each phase shift element may convert its respective non-DC divided voltage to a variable-amplitude DC voltage for driving its phase shifter.

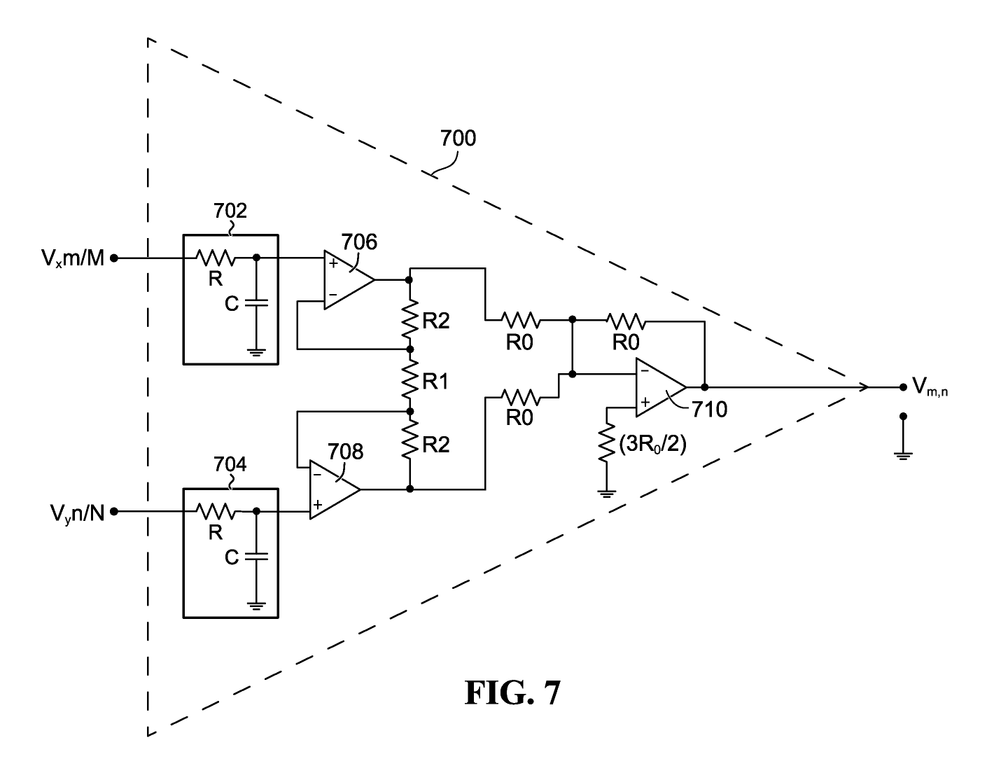

FIG. 7 is a diagram of an example voltage summing circuit 700 that may be used in a phase shift element in a phase controller, such as in the phase shift element 610 of the phase controller 600 shown in FIG. 6. One skilled in the art will appreciate that the voltage summing circuit 700 is provided as an example for illustrative purposes only, and will understand that many other implementations are possible.

The example voltage summing circuit 700 has a first input that is coupled to an input of a first LPF (low pass filter) 702. The first LPF 702 has an output that is coupled to a positive input of a first operational amplifier 706. The voltage summing circuit 700 has a second input that is coupled to an input of a second LPF 704. The second LPF 704 has an output that is coupled to a positive input of a second operational amplifier 708.

The first operational amplifier 706 has an output that is coupled to a first end of three serially coupled resistors having resistances of R2, R1 and R2, respectively, and that is also coupled to a first end of a first resistor having a resistance R0.

The second operational amplifier 708 has an output that is coupled to a second end of the three serially coupled resistors and that is also coupled to a first end of a second resistor having a resistance R0.

A negative input of the first operational amplifier 706 is coupled toward the first end of the three serially coupled resistors between the resistor with resistance R1 and the resistor with resistance R2.

A negative input of the second operational amplifier 708 is coupled toward the second end of the three serially coupled resistors between the resistor with resistance R1 and the resistor with resistance R2.

The first and second resistors having resistance R0 both have second ends that are coupled to a negative input of a third operational amplifier 710 and also coupled to a first end of a third resistor having resistance R0.

A positive input of the third operational amplifier 710 is coupled to a first end of a resistor having a resistance of 3R0/2, which resistor has a second end coupled to ground.

The third resistor having resistance R0 has a second end that is coupled to an output of the third operational amplifier 710, which is also coupled to an output of the voltage summing circuit 700.

In the illustrated example, the first and second LPFs 702, 704 are implemented with a simple RC circuit that includes a resistor with a first end coupled to the input of the LPF and a second end coupled to an output of the LPF, and a capacitor coupled between the output of the LPF and ground.

In operation, the voltages at the inputs of the voltage summing circuit 700 are first low-pass filtered by the LPFs 702 and 704, to mitigate the effects of RF and other EMI (electromagnetic interference) in the antenna array structure that may be picked up by the phase controller circuitry. The filtered input voltages are then applied to the positive inputs of the first and second operational amplifiers 706 and 708, respectively. The voltage at the output of the first operational amplifier 706 is equal to the voltage at its positive input plus the difference between the voltage at its positive input and the voltage at the positive input of the second operational amplifier 708, said difference being multiplied by the ratio of resistances R2/R1. The voltage at the output of the second operational amplifier 708 is equal to the voltage at its positive input plus the difference between the voltage at its positive input and the voltage at the positive input of the first operational amplifier 706, said difference being multiplied by the ratio of resistances R2/R1. The output voltage of the third operational amplifier 710 is the sum of the voltages at the outputs of the first and second amplifiers 706 and 708.

From the above, it can be seen that if the input voltages of the voltage summing circuit 700 were equal to

$${V}_{x} ( \frac{m}{M} ) and {V}_{y} ( \frac{n}{N} ) ,$$

respectively, then its output voltage would be

$${V}_{m , n} = {V}_{x} ( \frac{m}{M} ) + {V}_{y} ( \frac{n}{N} ) , \qquad ( 13 )$$

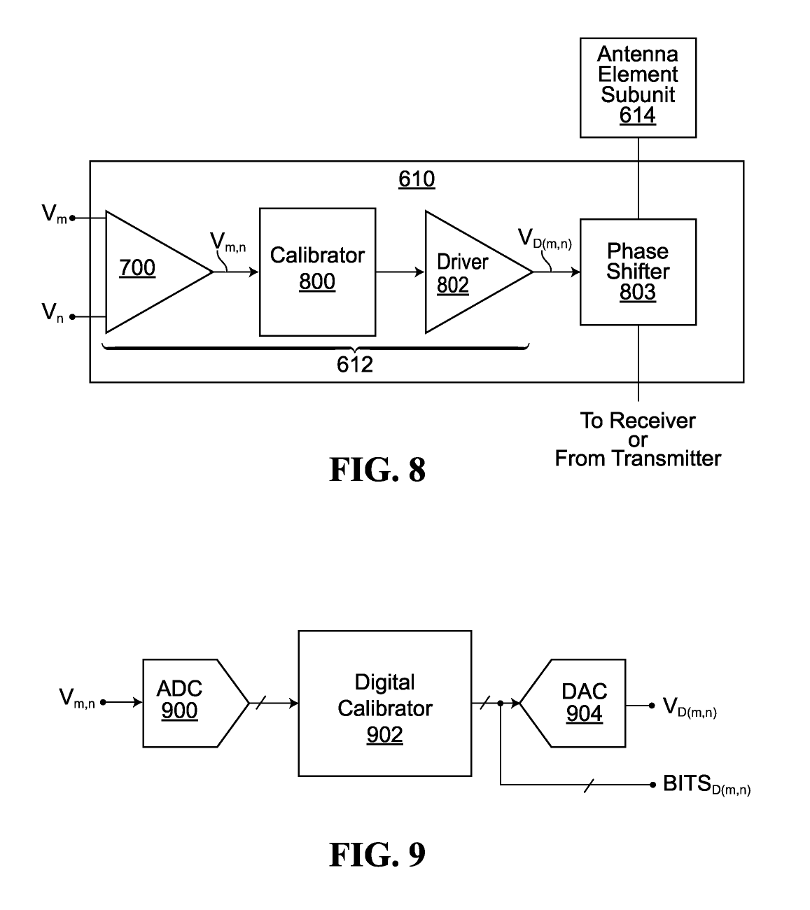

which effectively implements equation (12), without the offset voltage V₀. The offset voltage may be added in a subsequent stage as part of a calibration, which is discussed below with reference to FIGS. 8 and 9.

The resistor that is coupled to the positive input of the third operational amplifier 710 is included to mitigate the effects of any bias currents of the third operational amplifier 710, which in many cases are negligible. As such, it should be appreciated that this resistor is optional and may be omitted in many implementations.

Similarly, although the LPFs 702 and 704 may, in some cases, help mitigate the effects of RF and other EMI, they may be omitted in some implementations.

In some implementations, the LPF functionality could be used to convert a variable pulse-width-modulated (PWM) control voltage to corresponding varying DC voltages at the phase shift elements.

In some such implementations, reactive elements such as capacitors and inductors could be added around, or in place of, the voltage-divider resistors in the voltage dividers to filter the driving PWM waveform if doing so is deemed desirable from EMI or other perspectives.

The circuitry that may be included as part of the phase shift driver after a voltage summing circuit, such as the voltage summing circuit 700 shown in FIG. 7, will vary depending on the type of phase shifter employed in the phase shift element. Two examples of such driving circuitry will now be discussed with reference to FIGS. 8 and 9.

FIG. 8 is a block diagram of an example implementation of the phase shift element 610 that is part of the phase controller 600 shown in FIG. 6. In the example implementation, the phase shift element 610 includes a phase shift driver 612 and a phase shifter 803.

The driving circuit 612 shown in FIG. 8 includes a voltage summing device 700 (an example implementation of which is shown in FIG. 7), a calibrator 800 and a driver 802. The voltage summing device 700 has two inputs configured to receive divided voltages Vₘ and Vₙ, respectively. An output of the voltage summing device 700 is coupled to an input of calibrator 800. The calibrator 800 has an output that is coupled to an input of the driver 802. The driver 802 has an output that is coupled to an output of the phase shift driver 612. The output of the phase shift driver 612 is coupled to an input of the phase shifter 803. The voltage summing device 700, the calibrator 800, the driver 802, and the phase shifter 803 could be implemented in hardware.

As shown in the illustrated example, the phase shifter 803 may be coupled between an antenna element subunit 614 and a transmitter and/or receiver.

In operation, the voltage summing device 700 sums the divided voltages Vₘ and Vₙ at its inputs and passes the resulting sum V_{m,n} to the input of the calibrator 800. The calibrator 800 applies a calibration to the voltage output V_{m,n} of the voltage summing device 700, which may include applying a calibration factor and/or an offset to the voltage at its input. In some implementations, the calibrator 800 may also apply other calibration functions, such as temperature compensation and voltage biasing.

The driver 802 receives the output of the calibrator 800 and generates a calibrated phase shift control voltage suitable to drive the phase shifter 803 based on the output of the calibrator 800. The phase shifter 803 applies a phase shift to a signal associated with the antenna element subunit 614 dependent on the calibrated phase shift control voltage output of the driver 802. In some embodiments, the signal associated with the antenna element subunit 614 is a signal that the phase shifter 803 receives from a transmitter for transmission via the antenna element subunit 614. In some embodiments, the signal associated with the antenna element subunit 614 is a signal received at the phase shifter 803 via the antenna element subunit 614.

One skilled in the art will understand that the drive signals to drive a given phase shifter are implementation specific, depending on the type of phase shifter used. For example, types of phase shifters that may be used in some embodiments include, but are not limited to, switched-line, loaded-line, reflection, switched-filter, traveling-wave, ferrite, liquid-crystal and vector-modulator based phase shifters. As such, the particulars of the implementation of the driver 802 are implementation specific and are therefore not discussed here in detail. It may also be advantageous in some implementations to connect individual calibrator blocks at the inputs of the voltage summing circuit rather than its output.

FIG. 9 is a block diagram of an example implementation of the calibrator circuit that may be used in place of the calibrator 800 and the driver 802 in the phase shift driver 612 that is part of the phase shift element 610 shown in FIG. 8.

The calibrator circuit shown in FIG. 9 includes an ADC (analog to digital converter) 900, a digital calibrator 902 and a DAC (digital to analog converter) 904. The ADC 900 has an input that is configured to receive the output of a voltage summing device, such as the voltage summing circuit 700 shown in FIG. 7. The ADC 900 has a digital output that is coupled to an input of the digital calibrator 902, which has a digital output that is coupled to a digital input of the DAC 904, or it may also serve to drive a digital phase shifter directly, omitting the DAC. The DAC 904 has an analog output that is coupled to an input of an analog driving circuit such as 802. The calibrator 902 could be implemented in hardware, firmware, one or more components that execute software, or some combination thereof. For example, in one embodiment the calibrator 902 could be implemented in firmware, e.g. as a look-up table, that may be provisioned via software.

In operation, the ADC 900 converts the analog voltage output V_{m,n} of the voltage summing device to voltages representing the digital logic bits which encode the analog input voltage at each sample interval into a digital word. The calibrator 902 applies a digital calibration to the digital output word of the ADC 900, which may include applying a calibration factor and/or an offset to the digital word, or retrieving the appropriate corresponding digital word from a memory look-up table which would then be converted to the appropriate driving voltage for the phase shifter by the DAC 904. In some implementations, the digital calibrator 902 may also apply other digital calibration functions, such as temperature compensation and voltage biasing.

The DAC 904 converts the digital output of the digital calibrator 902 to generate an analog calibrated phase shift control voltage suitable to drive a given phase shifter.

In some implementations, a digital phase shifter controllable by a digital voltage input may be used. In some of such cases, the DAC 904 may be omitted and the calibrator 902 may be configured so that its digital output, shown as BITS_{D(m,n)} in FIG. 9, can be used to drive the digital phase shifter via short, local bit-lines.

In some cases, the phase shifts applied by a phase shift element in a phase controller may be applied to signals other than those interfacing directly to antenna elements, as for example to frequency-conversion local oscillator (LO) signals. In that case, the phase shifts may be implemented by elements other than phase shifters, as for example by frequency synthesizers.

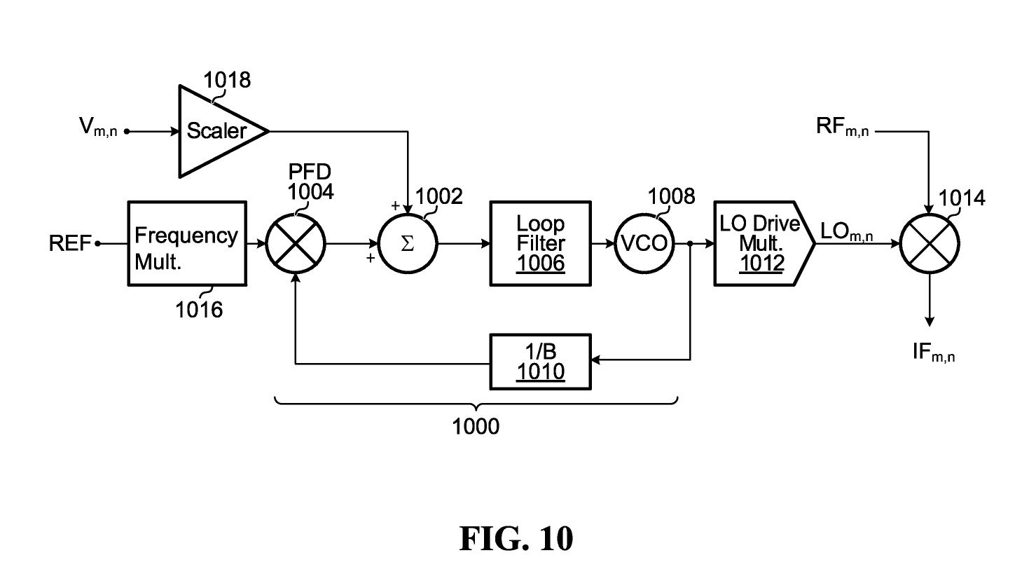

For example, the phase shifts could be applied to LO (local oscillator) signals at each antenna element subunit, each of which could contain a local frequency-conversion synthesizer and mixer (up-converter and/or down-converter) and front-end module, with the LO signal coherent among all modules. An example of such an implementation will now be discussed with reference to FIG. 10.

FIG. 10 is a block diagram of an example phase shift element implemented in a PLL (phase locked loop) 1000 in a down-converter. In FIG. 10, a voltage summing device, such as the voltage summing circuit 700 shown in FIG. 7, power-supply, ancillary and biasing voltages are not shown, to avoid congestion in the drawing.

The down-converter shown in FIG. 10 includes a multiplier 1014, (mixer) the PLL 1000, and may include a frequency multiplier 1016, an LO drive multiplier 1012, and a frequency-divider 1010. The phase shift element's input voltages would again be summed in an adder such as voltage summing circuit 700, whose output would then be applied to the input of a scaler 1018 and added into the PLL by adder 1002.

The PLL 1000 includes a PFD (phase-frequency detector), a loop filter 1006, a VCO (voltage controller oscillator) 1008 and may include a 1/B divider 1010.

The scaler 1018 has an input configured to receive a control voltage, which may, for example, be the output of a voltage summing circuit, such as the voltage summing circuit 700 shown in FIG. 7. The scaler 1018 has an output coupled to a first input of the adder 1002.

The frequency multiplier 1016 has an input configured to receive a reference frequency REF and an output coupled to a first input of the PFD 1004.

The PFD 1004 has an output coupled to a second input of the adder 1002.

The adder 1002 has an output coupled to an input of the loop filter 1006, which has an output connected to an input of the VCO 1008.

An output of the VCO 1008 is coupled to an input of the LO driver 1012 and to an input of the 1/B divider 1010.

An output of the 1/B divider 1010 is coupled to a second input of the PFD 1004.

An LO output LO_{m,n} of the LO driver 1012 is coupled to a first input of the multiplier 1014.

The multiplier 1014 has a second input configured to receive an RF input RF_{m,n}, and also has an IF output which outputs an IF signal IF_{m,n}.

In operation, the scaler 1018 applies an appropriate scaling to the voltage output V_{m,n} of the voltage summing circuit, which the adder 1002 applies as an offset to the output of the PFD 1004. The scaling could involve multiplication of the corresponding phase by the VCO feedback divider 1010 denominator “B” and division by the VCO output multiplier 1012 factor. In some cases, other scaling factors could be used, based on loop gain of the PLL, which in turn involves PFD sensitivity, VCO tuning sensitivity, and circuit (voltage, current, or conversions among them) gains, or possibly numerical scaling factors in case of digital PLL components. Full details of the operation of the PLL 1000 subsequent to the offset introduced by the adder 1002 are omitted for the sake of brevity, but it is noted that the introduction of the offset to the output of the PFD 1004 introduces a phase shift in the LO signal LO_{m,n}, which is then used by the multiplier 1014 to down-convert the RF signal RF_{m,n} to generate the IF output IF_{m,n}.

In some cases, the example driving circuits shown in FIGS. 8 and 9 may be applied to control the phases of RF or LO signals, or even IF signals, with appropriate scaling relative to the RF frequency of the array elements. One skilled in the art will appreciate that, while the phases to be effected may be the same at any of the mentioned frequencies (RF, IF, LO), the control signals for phase shifters may be scaled to effect the same phase in the different types of phase shifters that may be appropriate at each frequency. For example, if a true time-delay type of phase shifter could be used at RF, LO and IF, the control voltage intended to effect a given phase at RF, being linear with delay, may be scaled by a ratio of the RF/IF or RF/LO if applied to such a phase shifter at IF or LO, respectively, since phase=2*pi*Frequency*Delay, in radians.

While the foregoing example shows an application in a down-conversion PLL; applications in up-conversion PLLs are also contemplated.

Other configurations to implement the concept of controlling signal phase for an antenna array using voltage dividers are possible.

Returning now to FIGS. 5 and 6, the reference point about which the plane of the antenna array phase front is electronically “tilted” in these examples was chosen as one corner of the array and the variable control voltages were driven at one end of each voltage divider with the other end of the voltage dividers grounded. However, in some implementations, to reduce the range of RF phase shifts, the reference point of the antenna array may be chosen as the phase-center or physical center of the array, and the voltage dividers driven differentially, with the grounded or reference voltage of the dividers positioned at the array's phase reference.

If larger ranges of phase shift are to be used, modulo-2π functionality may be incorporated into the phase shift driver modules, or several phase shifters may be connected in series and respective voltages scaled correspondingly if true time-delay functionality is required.

In other implementations, parallel voltage dividers may be used in a grid pattern for better redundancy and/or failure protection, or for functions other than steering. In some cases, arbitrary subsets of antenna element subunits of a rectangular array of antenna element subunits could be populated with RF subunits and the same grid of parallel voltage dividers would still generate the correct steering voltages at the populated subunit locations without modifications, and steering would still be accomplished by setting only the same 2 independent control voltages.

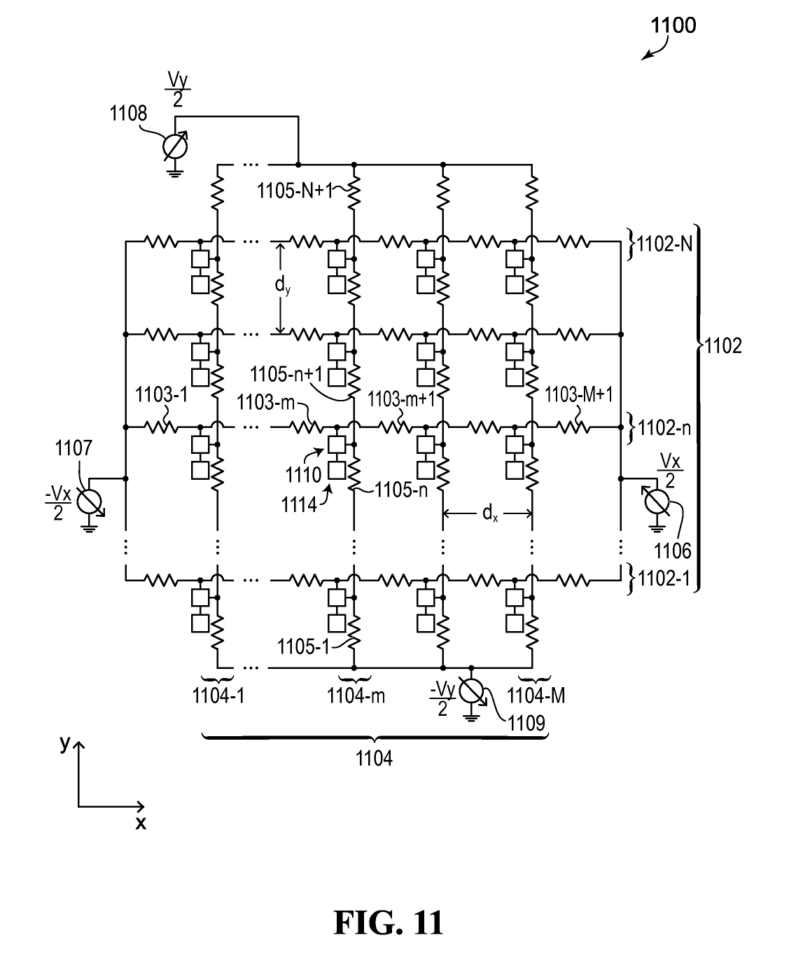

FIG. 11 is a diagram of another example phase controller that includes a grid of parallel voltage dividers for controlling phase in an M×N 2D planar antenna array having M columns of antenna element subunits arranged along a first direction x with a uniform spacing dₓ between adjacent columns and N rows of antenna element subunits arranged along a second direction y with a uniform spacing d_{y} between adjacent rows.

The phase controller 1100 includes a first voltage divider 1102 coupled at one end to a first variable voltage source 1107 and coupled at its other end to a second variable voltage source 1106, and a second voltage divider 1104 coupled at one end to a third variable voltage source 1109 and coupled at its other end to a fourth variable voltage source 1108.

The first voltage divider 1102 includes a first plurality of N parallel voltage dividers 1102-1 to 1102-N distributed along the second direction y. Each of the voltage dividers 1102-1 to 1102-N includes M+1 resistors 1103-1 to 1103-M+1 serially coupled together between the first variable voltage source 1107 and the second variable voltage source 1106. The second voltage divider 1104 includes a second plurality of M parallel voltage dividers 1104-1 to 1104-M distributed along the first direction x. Each of the voltage dividers 1103-1 to 1103-M includes N+1 resistors 1105-1 to 1105-N+1 serially coupled together between the third variable voltage source 1109 and the fourth variable voltage source 1108.

The phase controller 1100 also includes a plurality (M×N) of phase shift elements, each of which is coupled to the first voltage divider 1102, the second voltage divider 1104, and to a respective antenna element subunit of the plurality of M×N antenna element subunits of the planar antenna array. The phase shift element 1110 that is coupled to the antenna element subunit 1114 located at an m-th position of the planar array along the first direction and the n-th position of the planar array along the second direction is coupled to the m-th voltage divider 1104-m of the second plurality of voltage dividers distributed along the first direction and the n-th voltage divider 1102-n of the first plurality of voltage dividers distributed along the second direction.

The phase shift element 1110 has a first input coupled to the n-th voltage divider 1102-n at a voltage tap between the m-th resistor 1103-m and the m+1-th resistor 1103-m+1 to receive the m-th voltage Vₘ at the m-th resistor 1103-m. The phase shift element 1110 also has a second input coupled to the m-th voltage divider 1104-m at a voltage tap between the n-th resistor 1105-n and the n+1-th resistor 1105-n+1 to receive the n-th voltage Vₙ at the n-th resistor 1105-n.

All of the M×N phase shift elements may have the same structure in one embodiment. In other embodiments, the phase shift elements may not all have the same structure. In operation, the second variable voltage source 1106 and the first variable voltage source 1107 apply a first variable control voltage Vₓ across the first plurality of N voltage dividers 1102-1 to 1102-N, which each divide the first variable control voltage Vₓ into M+2 available voltages at their M+1 resistors 1103-1 to 1103-M+1. The fourth variable voltage source 1108 and the third variable voltage source 1109 apply a second variable control voltage V_{y} across the second plurality of M voltage dividers 1104-1 to 1104-M, which each divide the second variable control voltage V_{y} into N+2 available voltages at their N+1 resistors 1105-1 to 1105-N+1.

As shown, each of the N parallel voltage dividers 1102-1 to 1102-N of the first voltage divider 1102 includes M+1 resistors that divide the first variable control voltage Vₓ into M+2 available divided voltages. In the illustrated example, M of the M+2 available voltages generated by each of the N parallel voltage dividers 1102-1 to 1102-N of the first voltage divider 1102 are used to drive M columns of phase shift elements. Similarly, each of the M parallel voltage dividers 1104-1 to 1104-M of the second voltage divider 1104 includes N+1 resistors that divide the second variable control voltage V_{y} into N+2 available divided voltages. In the illustrated example, N of the N+2 available voltages generated by each of the M parallel voltage dividers 1104-1 to 1104-M of the second voltage divider 1104 are used to drive N rows of phase shift elements. This could change, depending on whether one chooses to connect the first and/or last row/column of phase shifters to the rail voltages, for example to arrange a convenient phase center of the array or ground potential of the differentially-driven voltage divider, depending on whether M and/or N is odd or even. With reference again to FIG. 6, it can be seen that the first voltage divider 602 includes M resistors that divide the first variable control voltage Vₓ into M+1 available voltages, to drive M columns of phase shift elements, and the second voltage divider 604 includes N resistors that divide the second variable control voltage V_{y} into N+1 available voltages, to drive N rows of phase shift elements. In the phase shift controller 600 shown in FIG. 6, each of the phase shift elements in the rightmost column is connected to the first variable voltage source 606, and each of the phase shift elements in the uppermost row is connected to the second variable voltage source 608.

In the illustrated example, the variable control voltages Vₓ and V_{y} are applied differentially across the first and second voltage dividers, respectively. In the example shown, the first variable voltage source 1107 is controlled to apply

$$- \frac{{V}_{x}}{2}$$

at one end of the first voltage divider 1102, and the second variable voltage source 1106 is controlled to apply

$$+ \frac{{V}_{x}}{2}$$

at the other end of the first voltage divider 1102. Similarly, the third variable voltage source 1109 is controlled to apply

$$- \frac{{V}_{y}}{2}$$

at one end of the second voltage divider 1104, and the fourth variable voltage source 1108 is controlled to apply

$$+ \frac{{V}_{y}}{2}$$

at the other end of the second voltage divider.

Each of the phase shift elements is connected and operates similarly to the phase shift element 610 of FIGS. 6 and 8.

Further example details of operation of the M×N phase shift elements will be described with reference to the phase shift element 1110 that is coupled to the antenna element subunit 1114 located at the m-th position in the first direction of the M×N planar antenna array and at the n-th position in the second direction of the M×N planar antenna array.

For the phase shift element 1110, its respective voltage of the M+2 available divided voltages generated by the n-th voltage divider 1102-n of the first voltage divider 1102 is the voltage Vₘ at the m-th resistor 1103-m taken at the voltage tap between the m-th resistor 1103-m and the m+1-th resistor 1103-m+1. The respective voltage of the N+2 available divided voltages generated by the m-th voltage divider 1104-m of the second voltage divider 1104 is the voltage Vₙ at the n-th resistor 1105-n taken at the voltage tap between the n-th resistor 1105-n and the n+1-th resistor 1105-n+1.

The phase shift element 1110 sums the voltages Vₘ and Vₙ in an embodiment, to generate a control voltage V_{m,n}.

The phase shift element 1110 applies a phase shift to a signal associated with the antenna element subunit 1114 dependent on the control voltage V_{m,n}.

Although not shown in FIG. 11, in some embodiments a steering controller may be coupled to the variable voltage sources 1106, 1107, 1108 and 1109 to control the two variable control voltage Vₓ and V_{y}.

As in the example phase controller 600 shown in FIG. 6, the phase controller 1100 shown in FIG. 11 allows for the control of the phase progression along the first direction x of the planar antenna array by controlling the variable control voltage Vₓ applied across the first voltage divider 1102 by the first and second variable voltage source 1107, 1106. Similarly, the phase controller 1100 allows for the control of the phase progression along the second direction y of the planar antenna array by controlling the variable control voltage V_{y} applied across the second voltage divider 1104. By controlling the phase progression along the two directions, the phase controller 1100 provides steering of the planar antenna array in two dimensions.

It is possible to obtain other useful phase-control functions using such voltage dividers formed by analog resistor networks, for example by making the resistance some non-linear function of its position in the array, and/or even connecting the grids together at the crossing points.

To create the effect of a lens, for instance, one could have concentric rings of resistivity increasing with the square of the radius, connected to a single variable voltage at the periphery and grounded at the center. A continuum analogy of such an arrangement is shown in FIGS. 12 and 13.

FIG. 12 is a diagram of a section of an example continuous resistance and FIG. 13 is a diagram of an example phase controller 1300 that is implemented with parallel coupled voltage dividers arranged in a manner analogous to the example continuous resistance shown in FIG. 12.

The section of a continuous resistive layer 1200 shown in FIG. 12 has a thickness t and is assumed to have a resistivity that is a quadratic function of radius, ρ(r), so that the resistance from the center to radius r₀ would be

$${\int }_{0}^{{r}_{0}} d R = {\int }_{0}^{{r}_{0}} \frac{ρ ( r ) d r}{t {\int }_{0}^{2 π} r d φ} . \qquad ( 14 )$$

With ρ(r)=αr², the equation (14) becomes

$$R ( r ) = {\int }_{0}^{r} d R = {\int }_{0}^{r} \frac{{ar}^{2} d r}{t 2 π r} = {\int }_{0}^{r} \frac{ar}{2 π t} d r = \frac{{ar}^{2}}{4 π t} . \qquad ( 15 )$$

The phase controller 1300 includes a plurality of parallel coupled voltage dividers 1308 that are arranged radially and coupled at one end to a ground and at another end to a variable voltage source 1306. For the sake of clarity, only one phase shift element 1310 is shown in FIG. 13. The phase shift element 1310 includes a phase shift driver 1312 and a phase shifter 1316, and is coupled to an antenna element subunit 1314.

The parallel coupled voltage dividers 1308 of the phase controller 1300 shown in FIG. 13 can be thought of as a set of series-connected concentric resistive rings having a resistance dR(r) between their inner radius r and outer radius r+dr. In principle then, only one radial string of resistors may be used to generate the divided voltages for the plurality of phase shift elements in the array, with individual resistance values found by differentiating the final term in equation (15) with respect to radius, r, and discretizing the resulting function of r. In this example, the resistance along a voltage divider with serially-connected discrete resistors having individual resistance values determined in the above manner would then be a quadratic function of the radius. For example, for a concentric ring antenna array with equally spaced concentric rings of antenna elements (e.g. one ring at a radius r₀, a second ring at a radius 2r₀, and a third ring at a radius 3r₀), the individual resistance values of the serially-connected resistors may be selected to increase linearly with the radius. In this example, if it is assumed that the first resistor has a resistance value R₀, the second resistor would be 3R₀, and the third resistor would be 5R₀, so that the resistance measured between radius r₀ and ground (center of circle) is R₀, and the resistance corresponding to radius 2r₀ is 4R₀ (i.e. R₀+3R₀) and the resistance corresponding to radius 3r₀ is 9R₀ (i.e. R₀+3R₀+5R₀).

The current through one of the voltage dividers 1308 would then be simply

$$I = \frac{{V}_{D}}{R ( D )} \qquad ( 16 )$$

for a maximum radius of D, and the voltage at any radius r would be

$$V ( r ) = IR ( r ) = \frac{{V}_{D} {ar}^{2}}{4 π tR ( D )} . \qquad ( 17 )$$

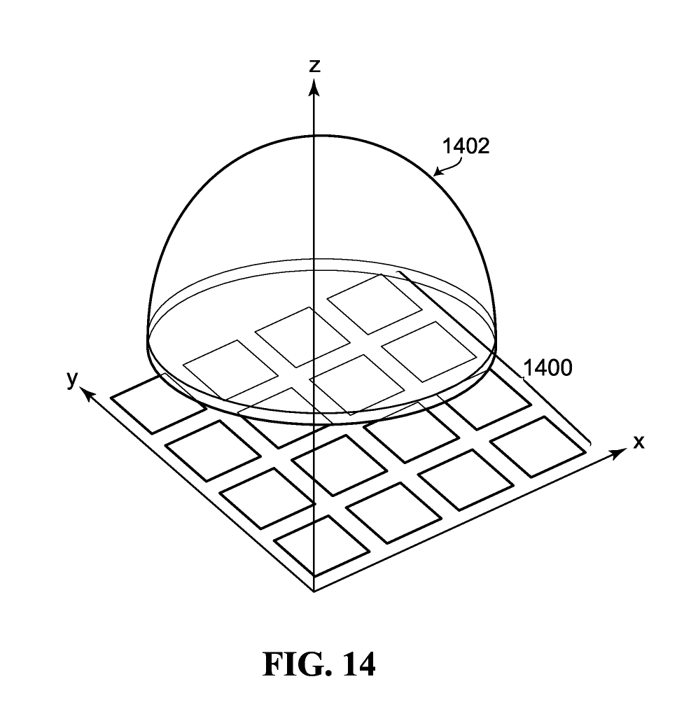

The driver 1312 for the array element 1314 at r takes the difference of V(r) and a fixed voltage V_{α} to generate a phase corresponding to the phase shift caused by the portion of a lens traversed by a wave at radius r. The focal length of the lens could be controlled by varying the driving voltage V_{D} applied by the variable voltage source 1306, thereby effectively varying the curvature of a virtual lens surface overlaid on the array. While the foregoing lens embodiment is described with respect to a concentric ring antenna array, more generally the above concept may be applied to any shape of array, with the same geometric phase and resistance progression applied to the elements of a different array shape. FIG. 14, for example, is a diagram of an example active radio frequency (RF) lens function 1402 overlaid on a 2D planar antenna array 1400.

As noted above, in principle the divided voltages for a lens function may be generated by a single voltage divider with serially-connected resistors having linearly increasing resistance values as described above. With the divided voltages taken at voltage tap points between the serially-connected resistors, the divided voltages could then be distributed to the phase shift elements through conductive wires and/or traces. In the case of a concentric ring antenna array, the conductive wires/traces may be arranged in a concentric ring geometry matching that of the antenna array. In other embodiments, where the antenna elements do not follow a circular concentric ring geometry, such as in the 2D planar antenna array 1400 shown in FIG. 14, the conductive wires/traces may still be routed in the general shape of concentric rings, with each phase shift elements connected to receive its respective divided voltage from the concentric ring conductive wire/trace nearest its associated antenna element.

Embodiments are described in detail above in the context of the illustrative examples in FIGS. 2 to 14. More generally, some embodiments relate to an apparatus to control signal phase for an antenna array.

In the example phase controllers shown in FIGS. 6, 11 and 13, the voltage dividers are implemented using serially coupled resistors with voltages taken at taps between the serially coupled resistors. In other embodiments, the voltage dividers may be implemented with continuous linear resistances with the plurality of voltages taken at points distributed along a length of the continuous linear resistance. In some cases, the plurality of voltages are taken at points distributed along the length of the continuous linear resistance with spacings between the points proportional to spacings of antenna element subunits distributed along a first direction of the antenna array. A component supplier could potentially fabricate or otherwise supply only a phase controller, or multiple phase controllers with an antenna array. Another possible supply chain includes one supplier that supplies phase controllers and another supplier that supplies antenna arrays. In either case, a phased antenna array could be constructed by coupling one or more phase controllers to an antenna array.

FIGS. 2 to 14 present illustrative examples. Other embodiments could include variations from these examples. For instance, phase controllers need not necessarily be coupled to an antenna array directly. There could be intervening components. With reference to FIG. 2, for example, the transmitter 210 could include one or more up-converters to convert signals from baseband to Intermediate Frequency (IF) and from IF to Radio Frequency (RF) for transmission. Phase shifts could be applied to IF signals in IF circuitry, further “back” in a transmit path than shown in FIG. 2 and within the transmitter 210. Another possible option would be to apply phase shifts to a signal in a Local Oscillator (LO) path that drives up-converter mixers. Shifting the phase of signals that drive such mixers affects the phase of the resultant mixed IF or RF signals. In a receive path, phase shifting could similarly be applied to IF signals in IF receive circuitry further along in the receive path than shown in FIG. 2, or to signals in an LO path that drives down-converter mixers. FIG. 10 is an illustrative example of how this may be implemented in one embodiment.

The present disclosure is also not in any way restricted to apparatus or communication equipment. Method embodiments are also contemplated.

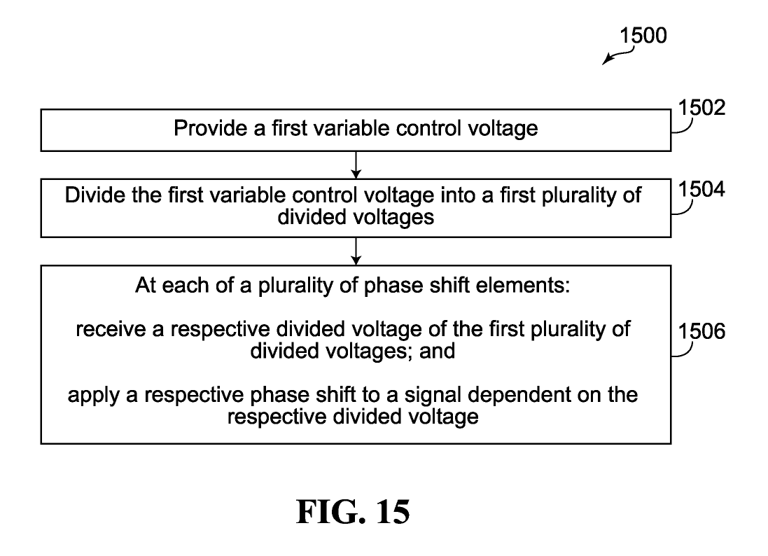

FIG. 15 is a flow diagram of an example method. The example method 1500 relates to phase control, and includes providing a first variable control voltage at 1502. At 1504, the first variable control voltage is divided into a first plurality of divided voltages. At 1506, each of a plurality of phase shift elements, receives a respective divided voltage of the first plurality of divided voltages, and applies a respective phase shift to a signal dependent on the respective divided voltage of the first plurality of divided voltages.

In some embodiments, each phase shift element is associated with a respective antenna element subunit in an antenna array, and applying a respective phase shift at 1506 includes applying a respective phase shift to a signal associated with the antenna element subunit with which the phase shift element is associated.

In some embodiments, the antenna element subunits in the antenna array are distributed along a first axis, and dividing the first variable control voltage at 1504 includes dividing the first variable control voltage such that the respective divided voltage received by each phase shift element is proportional to a position, along the first axis, of the antenna element subunit associated with the phase shift element.

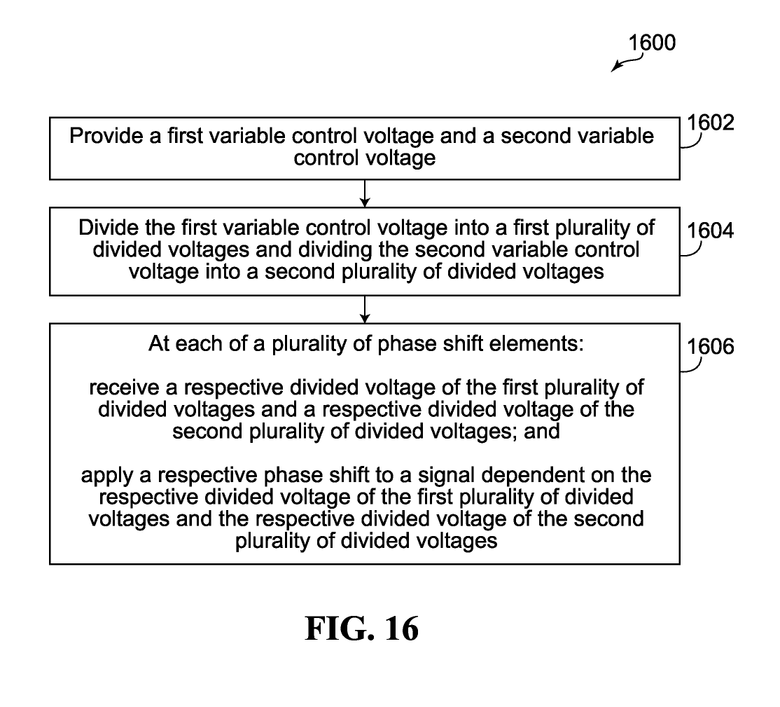

FIG. 16 is a flow diagram of another example method. The example method 1600 also relates to phase control. In the example shown, the method includes providing a first variable control voltage and a second variable control voltage at 1602. At 1604, the first variable control voltage is divided into a first plurality of divided voltages and the second variable control voltage is divided into a second plurality of divided voltages. At 1606, each of a plurality of phase shift elements receives a respective divided voltage of the first plurality of divided voltages and a respective divided voltage of the second plurality of divided voltages, and applies a respective phase shift to a signal dependent on the respective divided voltage of the first plurality and the respective divided voltage of the second plurality of divided voltages.

In some embodiments, each phase shift element is associated with a respective antenna element subunit in an antenna array, and applying a respective phase shift at 1606 includes applying a respective phase shift to a signal associated with the antenna element subunit with which the phase shift element is associated.

In some embodiments, the antenna element subunits in the antenna array are distributed along a first axis and a second axis, and dividing the first and second variable control voltages at 1604 includes dividing each of the first and second variable control voltages such that the respective divided voltages, of the first and second plurality of divided voltages, received by each phase shift element are proportional to positions, along the first and second axis of an antenna array, respectively, of the antenna element subunit associated with the phase shift element.

In some embodiments, applying a respective phase shift to the signal at 1604 includes summing the respective divided voltage of the first plurality of divided voltages and the respective divided voltage of the second plurality of divided voltages, and applying a respective phase shift to the signal dependent on the resulting sum. In some cases, a calibration factor and/or an offset may be applied to the resulting sum to generate a calibrated phase shift control voltage and the respective phase shift applied at 1606 is applied to the signal dependent on the calibrated phase shift control voltage.

The example methods 1500 and 1600 are illustrative of example embodiments. In other embodiments, similar or different operations could be performed in a similar or different order. Various ways to perform the illustrated operations, as well as examples of other operations that may be performed, are described herein. Further variations may be or become apparent.

It should be noted that, although the example phase controllers 600, 1100 and 1300 shown in FIGS. 6, 11 and 13, respectively, are shown as being driven by variable voltage sources, in the variable voltage sources could be replaced with corresponding variable current sources.

Various other phase functions could be implemented by this general analog method of phase shifter control in an antenna array, such as gratings, or transmission properties. Functions of the control voltages may be implemented via the resistors comprising the voltage dividers and via calibration and offset functions in the driving circuits, or a combination thereof.

Methods, equipment and apparatuses in accordance with some embodiments disclosed herein could involve the control of only one or two external voltages for steering any phased array (or setting its focal properties), and routing only a small, fixed number of common analog lines to phase shifters. This may at least partially mitigate one or more problems associated with controlling a large number of phase shifters in a phased array of antenna elements, local oscillators, or in an active lens.

Although some of the illustrative examples described herein have been described in the context of simple point-to-point fixed radio links, more generally aspects disclosed herein can be applied in other contexts such a mobile links, radar, or any other radio application that may require the steering or focusing of the beam of an antenna array.

Phase shifter control in accordance with some embodiments disclosed herein can be readily extended to arbitrary shapes of arrays, including sparse arrays, potentially without the need for extensive computations of the individual phase settings.

In some embodiments, by positioning the voltage divider elements in direct proportions to the antenna element subunit spacings, the correct phase shift setting voltage is automatically generated locally for each antenna element subunit from only the one or two external control voltages.

Methods, equipment and apparatuses in accordance with some embodiments disclosed herein could be particularly advantageous for controlling high-frequency arrays of many elements, which tend to have little extra room for control circuitry, as in some cases only two control voltages can control any number, P=N×M of antenna element subunits of a rectangular N×M array instead of using P separate multi-bit control signals.

Numerous modifications and variations of the present application are possible in light of the above teachings. It is therefore to be understood that within the scope of the appended claims, the application may be practised otherwise than as specifically described herein. Although the present disclosure refers to specific features and embodiments, various modifications and combinations can be made. The specification and drawings are, accordingly, to be regarded simply as an illustration of embodiments of the invention as defined by the appended claims, and are contemplated to cover any and all modifications, variations, combinations, or equivalents. Thus, it should be understood that various changes, substitutions and alterations can be made herein without departing from the invention as defined by the appended claims.

Moreover, the scope of the present application is not intended to be limited to particular embodiments of any process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments disclosed herein may be utilized. Accordingly, the appended claims are intended to include within their scope such processes, machines, manufacture, compositions of matter, means, methods, or steps

For example, any of various applications of phase control are possible. One possible market for embodiments disclosed herein is for 5G millimeter wave radios that can be used in a backhaul application where a phased array is used, for instance. Another possible application is for a very high data rate Base Transceiver Station (BTS) or user equipment application, again where a phased array is used. Other applications are also possible.

In addition, although described primarily in the context of methods, apparatus and equipment, other implementations are also contemplated. Through the disclosure provided herein, embodiments may be implemented by using hardware only or by using a hardware platform to execute software, for example. Embodiments in the form of a software product are also possible. A software product may be stored in a nonvolatile or non-transitory storage medium, which could be or include a compact disk read-only memory (CD-ROM), USB flash disk, or a removable hard disk. More generally, a storage medium could be implemented in the form of one or more memory devices, including solid-state memory devices and/or memory devices with movable and possibly even removable storage media. Such a software product includes a number of instructions, stored on the storage medium, that enable a processor or computer device (personal computer, server, or network device, for example) to execute methods as disclosed herein.

We claim:

1. A phase control apparatus, comprising:
a first control voltage source for providing a first variable control voltage;
a first voltage divider to divide the first variable control voltage into a first plurality of divided voltages; and
a plurality of phase shift elements, each coupled to the first voltage divider to receive a respective divided voltage of the first plurality of divided voltages, each phase shift element applying a respective phase shift to a signal received at an input of the phase shift element dependent on a magnitude of its respective divided voltage.

2. The apparatus of claim 1, wherein each phase shift element is configured to apply its respective phase shift to a signal associated with a respective antenna element subunit in an antenna array.

3. The apparatus of claim 2, wherein the antenna element subunits in the antenna array are distributed along a first axis.

4. The apparatus of claim 3, wherein the respective divided voltage received by each phase shift element is proportional to a position, along the first axis, of the antenna element subunit associated with the phase shift element.

5. The apparatus of claim 4, wherein the antenna element subunits in the antenna array are also distributed along a second axis.

6. The apparatus of claim 5, further comprising:
a second control voltage source for providing a second variable control voltage; and
a second voltage divider to divide the second variable control voltage into a second plurality of divided voltages,
wherein each phase shift element of the plurality of phase shift elements is coupled to the second voltage divider to receive a respective divided voltage of the second plurality of divided voltages, each phase shift element applying its respective phase shift further dependent on a magnitude of its respective divided voltage of the second plurality of divided voltages.

7. The apparatus of claim 6, wherein the respective divided voltage, of the second plurality of divided voltages, received by each phase shift element is proportional to a position, along the second axis, of the antenna element subunit associated with the phase shift element.

8. The apparatus of claim 7, further comprising the antenna array, wherein the antenna element subunits are distributed in a planar array in a plane defined by the first axis and the second axis.

9. The apparatus of claim 8, wherein:
the antenna element subunits are arranged in the planar array in a grid pattern in columns along the first axis of the antenna array and in rows along the second axis of the antenna array,
the first voltage divider comprises a first plurality of voltage dividers coupled together in parallel and distributed along the second axis of the antenna array,
the second voltage divider comprises a second plurality of voltage dividers coupled together in parallel and distributed along the first axis of the antenna array, and
the plurality of phase shift elements are coupled to the first voltage divider and the second voltage divider, with the phase shift element that is coupled to the antenna element subunit that is located at an m-th position of the planar array along the first axis and the n-th position of the planar array along the second axis being coupled to the m-th voltage divider of the second plurality of voltage dividers distributed along the first axis and the n-th voltage divider of the first plurality of voltage dividers distributed along the second axis.

10. The apparatus of claim 1, wherein each phase shift element of the plurality of phase shift elements comprises a phase shift driver configured to apply at least one of: a calibration factor and an offset, to the respective divided voltage to generate a calibrated divided voltage, wherein each phase shift element is configured to apply its respective phase shift dependent on a magnitude of the calibrated divided voltage generated by its phase shift driver.

11. The apparatus of claim 1, wherein the first variable control voltage is provided by applying a positive voltage at a first end of the first voltage divider and a negative voltage at a second, opposite end of the first voltage divider.

12. The apparatus of claim 6, wherein each phase shift element of the plurality of phase shift elements comprises a phase shift driver configured to sum the respective divided voltage of the first plurality of divided voltages and the respective divided voltage of the second plurality of divided voltages, wherein each phase shift element is configured to apply its respective phase shift dependent on the resulting sum.

13. The apparatus of claim 12, wherein the phase shift driver is further configured to apply at least one of: a calibration factor and an offset, to the resulting sum to generate a calibrated phase shift control voltage, wherein each phase shift element is configured to apply its respective phase shift dependent on the calibrated phase shift control voltage generated by its phase shift driver.

14. The apparatus of claim 3, wherein the respective divided voltage received by each phase shift element is proportional to a non-linear function of a position, along the first axis, of the antenna element subunit associated with the phase shift element.

15. Communication equipment comprising:
an antenna array, the antenna array comprising a plurality of antenna element subunits;
a phase controller comprising an apparatus as claimed in claim 1, coupled to the plurality of antenna element subunits.

16. A phase control method comprising:
providing a first variable control voltage;
dividing the first variable control voltage into a first plurality of divided voltages; and
at each of a plurality of phase shift elements: receiving a respective divided voltage of the first plurality of divided voltages; and applying a respective phase shift to a signal dependent on a magnitude of the respective divided voltage of the first plurality of divided voltages.

17. The method of claim 16, wherein applying a respective phase shift comprises applying a respective phase shift to a signal associated with a respective antenna element subunit in an antenna array.

18. The method of claim 17, wherein the antenna element subunits in the antenna array are distributed along a first axis, and dividing the first variable control voltage comprises dividing the first variable control voltage such that the respective divided voltage received by each phase shift element is proportional to a position, along the first axis, of the antenna element subunit associated with the phase shift element.

19. The method of claim 18, wherein the antenna element subunits in the antenna array are also distributed along a second axis, the method further comprising:
providing a second variable control voltage;
dividing the second variable control voltage into a second plurality of divided voltages; and
at each of the plurality of phase shift elements: receiving a respective divided voltage of the second plurality of divided voltages; and applying the respective phase shift further dependent on a magnitude of the respective divided voltage of the second plurality of divided voltages.

20. The method of claim 19, wherein dividing the second variable control voltage comprises dividing the second variable control voltage such that the respective divided voltage, of the second plurality of divided voltages, received by each phase shift element is proportional to a position, along the second axis, of the antenna element subunit associated with the phase shift element.

21. The method of claim 20, wherein applying the respective phase shift to the signal comprises:
summing the respective divided voltage of the first plurality of divided voltages and the respective divided voltage of the second plurality of divided voltages; and
applying the respective phase shift to the signal dependent on the resulting sum.

22. The method of claim 21, wherein applying the respective phase shift to the signal further comprises:
applying at least one of a calibration factor and an offset to the resulting sum to generate a calibrated phase shift control voltage; and
applying the respective phase shift to the signal dependent on the calibrated phase shift control voltage.
